(19) United States
(12) Patent Application Publication
(10) Pub. No.: US 2015/0296608 A1
(43) Pub. Date: Oct. 15, 2015

(54) RFID SHIELDING

(71) Applicants: Jeff MCFADDEN, Rochester, NY (US); Brian P. MCFADDEN, Largo, FL (US); Bruce V. MUTTER, Princeton, WV (US); Heather N. WILLIAMS, Lindside, WV (US); John S. BROWNING, JR., Oakwood, VA (US)

(72) Inventors: Jeff MCFADDEN, Rochester, NY (US); Brian P. MCFADDEN, Largo, FL (US); Bruce V. MUTTER, Princeton, WV (US); Heather N. WILLIAMS, Lindside, WV (US); John S. BROWNING, JR., Oakwood, VA (US)

(73) Assignee: MOBILE DYNAMIC MARKETING, INC., Largo, FL (US)

(21) Appl. No.: 14/683,678

(22) Filed: Apr. 10, 2015

Related U.S. Application Data
(60) Provisional application No. 61/979,397, filed on Apr. 14, 2014.
(60) Provisional application No. 62/033,063, filed on Aug. 4, 2014.
(60) Provisional application No. 62/033,082, filed on Aug. 4, 2014.
(60) Provisional application No. 62/033,074, filed on Aug. 4, 2014.
(60) Provisional application No. 62/033,385, filed on Aug. 5, 2014.

(51) Int. Cl. H05K 1/02; H05K 1/09; H02J 7/00

(52) U.S. Cl. CPC H05K 1/0219; H02J 7/0052; H05K 1/092; H05K 1/0296; H05K 2201/10083; H05K 2201/10037; H05K 2201/10098

(57) ABSTRACT

An RFID shield in the form of a thin plastic substrate upon which a shielding pattern is printed in conductive paint or ink. The pattern may cover the entire surface of the substrate or it may be in the form of intersecting lines or arrays of intersecting elements.

The present application claims priority from the following applications: Application 61/979,397 filed 14 Apr. 2014; Application 62/033,063 filed 4 Aug. 2014; Application 62/033,082 filed 4 Aug. 2014; Application 62/033,074 filed 4 Aug. 2014; Application 62/033,085 filed 4 Aug. 2014 and Application 62/033,078 filed 4 Aug. 2014.

### BACKGROUND OF THE INVENTION

Radio frequency identification (RFID) chips are increasingly found embedded in various devices including credit cards, driver licenses, passports, etc. Such chips contain a significant amount of personal data such as the holder's name, address, social security number, account information, employee number and the like, which is of high value to identity thieves. There are available devices which can be utilized to read such data from as far as 10 feet or so. Unfortunately, when such devices fall into the hands of unscrupulous people, they enable the undetected reading of such data from unsuspecting victims in public places such as malls, coffee shops etc. Upon harvesting the data on a holder's card, the identity thief is able to program the data on its own card thereby enabling the thief's cloned card to respond in an identical fashion as the holder's legitimate card.

Heretofore it has been suggested to provide shielding to prevent the unauthorized reading of RFID chips, in the form of metallic cases, which, while effective, are awkward and cumbersome to carry and use. It is thus a principal object of the present invention to provide effective and efficient RFID shielding in a form that may be conveniently and comfortably carried in a user's pocket, purse or wallet.

### SUMMARY OF THE INVENTION

In accordance with the present invention, the above and other beneficial objects are attained by providing an RFID shield in the form of a substrate upon which a shielding pattern is printed in conductive paint or ink. The pattern may cover the entire surface of the substrate or it may be in the form of intersecting lines or arrays of intersecting elements. The pattern may be in the form of a spiral antenna, a patch antenna, a fractal antenna or a combination of a spiral, patch or fractal antenna. The antenna may be passive or made active by providing a lithium flat pack battery and piezoelectric elements to charge the battery based on normal movement of the user. Alternatively, the shielding may be provided by a smartphone app utilizing the near field communication (NFC) hardware and high speed receiver sections in the phone to detect when a surreptitious signal is being read and to generate a bogus signal in response.

### BRIEF DESCRIPTION OF THE DRAWINGS

In the accompanying drawings:

FIG. 1 is an exploded plan view of a stack of RFID credit cards sandwiched between a pair of RFID shields in accordance with the present invention.

FIG. 2 is an end view of the stack of RFID credit cards sandwiched between a pair of RFID shields;

FIG. 3 is first embodiment of a conductive pattern printed on a plastic substrate of the RFID shield;

FIG. 4 is an alternative conductive pattern;

FIG. 5 is another conductive pattern;

FIG. 6 is another conductive pattern;

FIG. 7 is a partial side view of the RFID shield of the present invention provided with non-conductive protective sheets;

FIG. 8 is plan view of a RFID shield wherein the printed conductive pattern is in the form a spiral and a fractal antenna; and,

FIG. 9 is a plan view of a powered RFID shield.

### DETAILED DESCRIPTION OF THE PREFERRED EMBODIMENT

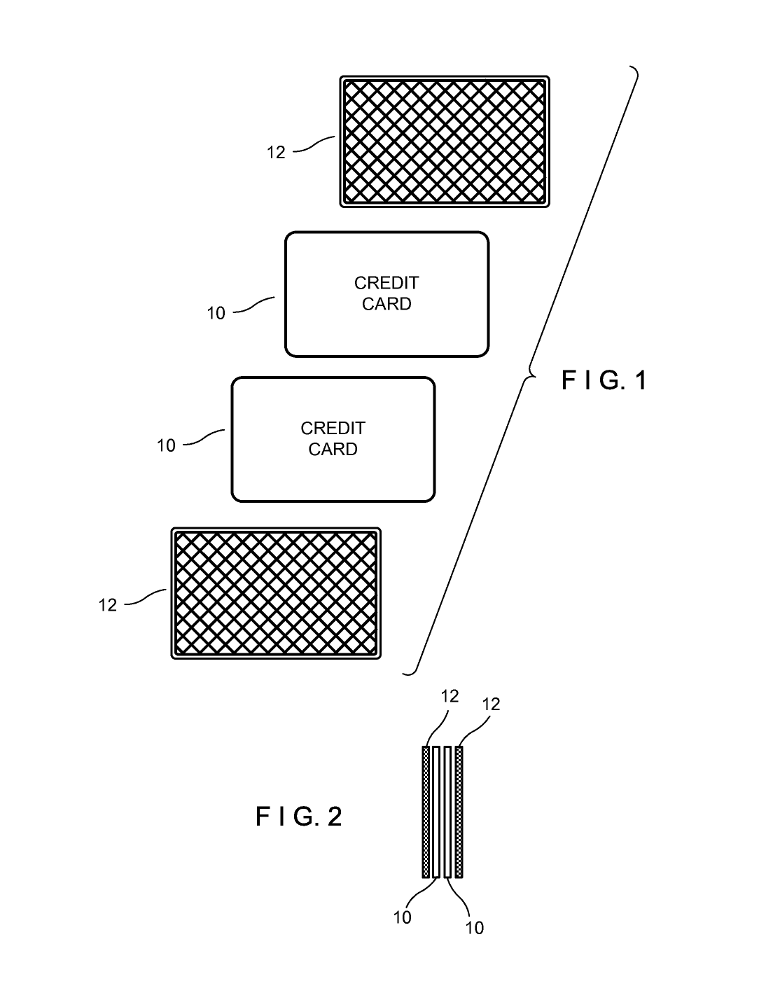

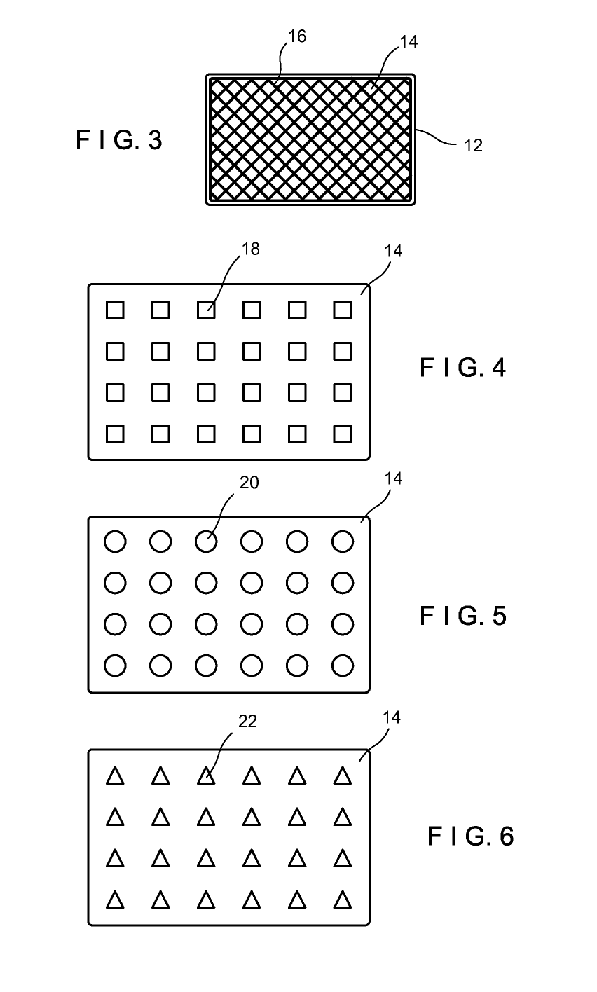

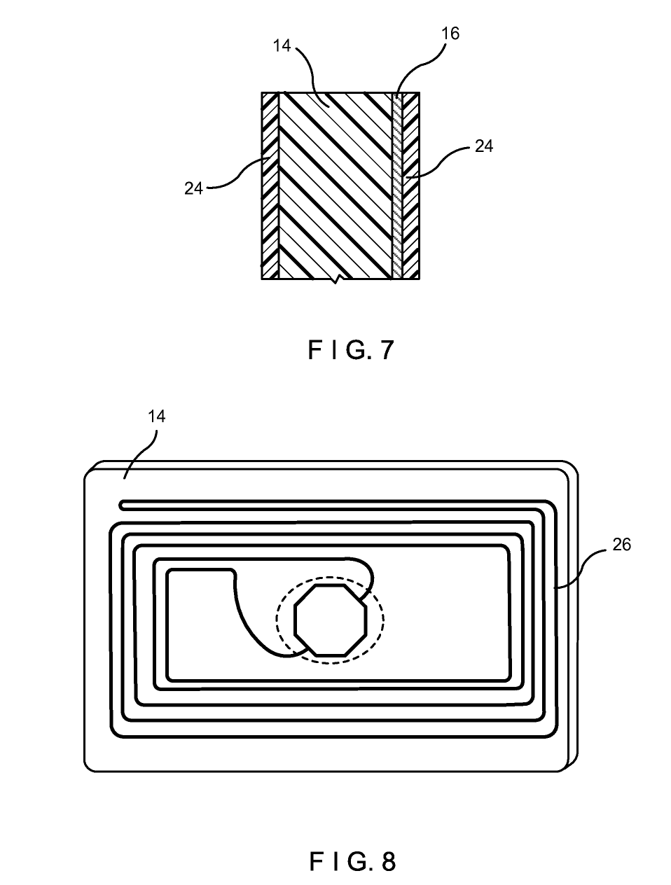

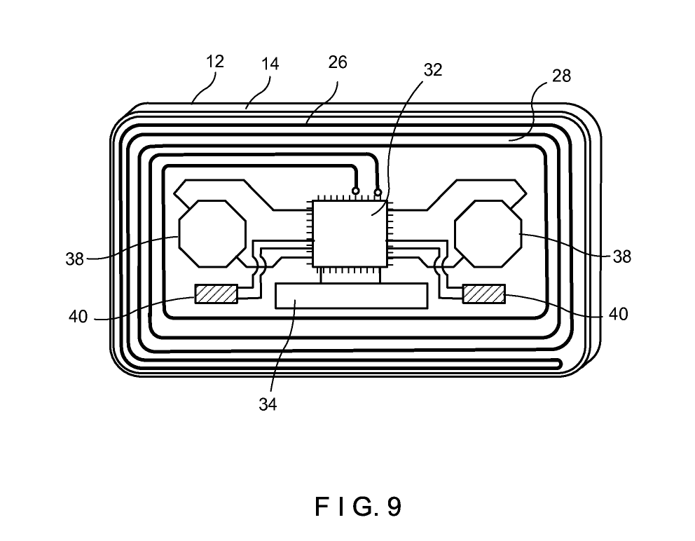

Reference is now made to the drawings and to FIGS. 1 and 2 in particular wherein a stack of credit cards 10 is shown. The stack of cards 10 may be sandwiched between a pair of RFID shields 12 although a single shield has been found to provide effective protection even when the stack of cards is offset as in a billfold. While the stack is shown as consisting of two credit cards 10, it may comprise a lessor or greater number. Each of the shields 12 comprises a substrate 14 printed with a conductive ink or paint. Such inks are readily available from several sources including E. I. du Pont Nemours and Company. The substrate is a relatively thin plastic sheet, either thermoplastic or thermosetting of credit card size and between 0.5 and 50 mils thick. The substrate may be covered with the conductive ink or the conductive ink may be printed or silk screened with a pattern 16 comprising cross hatched intersecting uninterrupted lines as shown in FIG. 3 or elements 18, 20, 22 arranged in an intersecting array. To protect the conductive ink, the printed substrate 14 may be covered with a thin plastic non-conductive sheet 24 or laminated between thin plastic non-conductive sheets 24. The sheet or sheets 24 may carry a logo or graphics. Alternatively, the protective layer may be a non-conductive paint or ink layer. The conductive ink/paint may be solvent or UV curable, loaded with silver, carbon or other conductive material to provide a conductivity of between 0.01 to 50 ohms/square.

For more effective shielding, the printed conductive pattern 16 may be in the form of an antenna 26 as shown in FIG. 8. In this case, the pattern functions as an antenna system receiving incident electromagnetic energy from an interrogation transmitter effectively eliminating the possibility of the RFID chip on a protected card communicating with the interrogation device. In this case, the pattern 16 is configured as a spiral antenna as shown in FIG. 8. Alternatively, the conductive layer may be configured as a patch antenna, a fractal antenna or a combination of a spiral, patch or fractal antenna.

The shielding described above may be considered to be passive. Alternatively, the shield 12 may be made active by providing a high speed receiver section 32 attached to antenna 26, which includes a spiral transmit/receive antenna 28 and a fractal patch antenna 30. When the high speed receiver section 32 detects attempt to interrogate the protected RFID chip it transmits a jamming signal. The shield is powered by a flat pack lithium battery which may be kept charged through normal motion of the device while in a user's wallet or purse through a pair of piezoelectric charging components 40. Similarly, since today's smartphones contain embedded Near Field Communication (NFC) hardware, by placing the smartphone in proximity with the RFID chips to be protected an app may be provided to utilize the high speed receiver section within the phone to detect attempts to interrogate the RFID chips being protected. The app will poll for RFID read attempts and when an interrogating signal is detected, the smartphone will transmit a jamming signal consisting of bogus data thereby protecting both the RFID chip data as well as any data on the phone. The app can be shut off for NFC communication when desired.

Thus, in accordance with the above, the aforementioned objectives are effectively attained.

Having thus described the invention, what is claimed is:

1. An RFID shield comprising:
a substrate having a major axis and a minor axis and
a printing on one surface of the substrate, said printing being formed with a conductive ink or a paint and extending substantially from edge to edge of the substrate.

2. The RFID shield in accordance with claim 1 wherein the printing covers the entire surface of the substrate.

3. The RFID shield in accordance with claim 1 wherein the printing comprises a first set of lines and a second set of lines, said first and second sets of lines intersecting each other.

4. The RFID shield in accordance with claim 1 wherein the printing comprises an array of intersecting elements.

5. The RFID shield in accordance with claim 4 wherein the elements are identical.

6. The RFID shield in accordance with claim 1 wherein the printing comprises an RFID antenna.

7. The RFID shield in accordance with claim 6 wherein the printing comprises a spiral antenna.

8. The RFID shield in accordance with claim 6 wherein the printing comprises a patch antenna.

9. The RFID shield in accordance with claim 6 wherein the printing comprises a fractal antenna.

10. The RFID shield in accordance with claim 6 wherein the printing comprises two or more of a spiral antenna, a patch antenna and a fractal antenna.

11. The RFID shield in accordance with claim 6 further comprising
a high speed receiver/transmitter attached to the RFID antenna, said high speed receiver/transmitter being adapted to transmit a jamming signal in response to an incoming interrogating signal.

12. The RFID shield in accordance with claim 11 further comprising a power source attached to the high speed receiver/transmitter.

13. The RFID shield in accordance with claim 12 wherein said power source comprises a rechargeable battery and further comprising a piezoelectric recharging component attached to said rechargeable battery.

14. An RFID shield comprising a smartphone having Near Field Communication (NFC) hardware and a high speed receiver section, said smartphone being configured to poll for RFID read attempts in the form of in-coming interrogating signals and to transmit a jamming signal containing bogus data in response to detection of an in-coming interrogating signal.
